(19) United States
(12) Patent Application Publication
(10) Pub. No.: US 2008/0090739 A1
(43) Pub. Date: Apr. 17, 2008

(54) Masked Solid Porous Supports Allowing Fast And Easy Reagent Exchange To Accelerate Electrode-Based Microarrays

(76) Inventors: Marinus Gerardus Johannes Van Beuningen, Oss (NL); Hendrik Sibolt Van Damme, Den Bosch (NL); Richard De Wijn, Nijmegen (NL); Jurry Maurice Hannink, Nijmegen (NL); Colin John Ingham, Wageningen (NL)

Correspondence Address: AMSTER, ROTHSTEIN & EBENSTEIN LLP, 90 PARK AVENUE, NEW YORK, NY, 10016, US

(21) Appl. No.: 11/662,397

(22) PCT Filed: Sep. 28, 2005
(86) PCT No.: PCT/EP05/10465

§ 371 Date: Jun. 18, 2007

(30) Foreign Application Priority Data
Sep. 30, 2004 (EP) 04447216.5

(51) Int. Cl. C40B 60/12; C23C 14/34; C25D 7/00

(52) U.S. Cl. 506/39; 204/192.1; 205/80

(57) ABSTRACT

Solid porous supports find use in array analysis, as they offer high surface area for contacting the analyzed sample. The present invention provides a solid porous support suitable for array analysis having first and second surfaces, and comprising channels extending from said first surface to said second surface, characterised in that at least one conductive material is applied to predefined regions on said first surface and/or on said second surface and/or inside the channels contained within said solid porous support. Such conductive material(s) may form a high-precision grid delineating physically distinct compartments within the support and thus reduce the risk of cross-contamination in array analysis. Additionally, such conductive material(s) may directly participate in reactions performed on the array by means of their electrical and/or thermal conductivity.

### FIELD OF THE INVENTION

The present invention relates to solid porous supports suitable for array analysis. In particular, the present invention relates to solid porous supports, whereon an additional material may be applied in a predefined pattern. More specifically, in the context of the present invention such material may form a grid or a mask delineating distinct compartments within the support.

### BACKGROUND TO THE INVENTION

The present invention relates to solid porous supports finding use in array analysis, offering high surface area for contacting the analyzed sample. In flow-through porous supports the kinetics of the desired analysis reaction can be accelerated by repeated pumping of the sample through the pores or channels of the support, as described in for example U.S. Pat. No. 6,383,748 B1.

To prevent the diffusion of samples and subsequent cross-contamination between different samples, individual reactions may be confined to distinct compartments within the porous support by creating a grid or a mask on the surface of the support or through the entire height or thickness of the support. Pores or channels in the resulting distinct compartments separated by the grid may be exposed to samples or reactants, or may harbor living cells or organisms without the risk of cross-contamination with the contents of neighboring compartments.

For example, such grid or mask may be produced by applying a polymer solution on the surface of the support in a predefined pattern. The polymer solution enters the pores and channels of the support and solidifies to produce the resulting grid. For example, PCT/EP2005/004230 discloses a method to produce such through-going grid or mask using a polymeric material, more particularly latex polymer.

Although said polymeric materials have been proven to be very useful for creating such grids, some applications may require the use of other materials improving the precision of deposition of such grid. In addition, useful physical and/or chemical qualities of such other materials applied to the porous support in the form of said grid or in another pattern, may enable new types of assays to be carried out on the porous support. Such useful physical and/or chemical qualities may for example comprise electrical conductivity or thermal conductivity.

### SUMMARY OF THE INVENTION

The present invention provides solid porous supports characterized in the presence of a pattern of deposited material(s), wherein said material allows high-precision deposition thereof. Within the present invention, the deposited material is characterized by being conductive compared to the solid porous support onto which and/or within which it is deposited.

Accordingly, the present invention provides a solid porous support suitable for array analysis having first and second surfaces, and comprising channels extending from said first surface to said second surface, characterised in that at least one conductive material is applied to predefined regions on said first surface and/or on said second surface and/or inside the channels contained within said solid porous support.

Said conductive material may form a grid delineating physically distinct compartments on the surface(s) of and/or within the support, thereby reducing the risk of cross-contamination in array analysis. Said conductive material(s) may also form a part of an electronic circuit on the surface(s) of and/or within the porous support. Within the present invention, the material used to produce such grid may comprise carbon or a metal in its metallic form, or a combination or an alloy of the latter. As known in the art, deposition of metals (e.g., metal particles) on support surfaces can be done with excellent precision of deposition. Therefore, the grid or other patterns produced on the surface of and/or within the porous support will have a narrower and a more precise delineation than may be achieved using current methods. In addition to the conductivity characteristics of the deposited material(s), a pattern with narrower and more precise delineation will in turn enable increasing the number and/or size of samples analyzed per unit area of the support, leading to improved throughput of the array analysis.

An added benefit of the present invention is the ability of the conductive material(s) to directly participate in the analysis reactions performed on and/or within the porous support. For example, thermally conductive materials may be used to manipulate the temperature of the analyzed sample. In another example, electrically conductive materials may deliver voltage potential and/or electrical current to the analyzed sample. This may for example attract or repulse charged molecules within the sample to electrically activated areas on or within the porous support, resulting for example in accelerated binding of sample molecules.

### DETAILED DESCRIPTION OF THE INVENTION

Before the devices and methods of the present invention are described, it is to be understood that this invention is not limited to particular devices and methods as such devices and methods may, of course, vary. It is also to be understood that the terminology used herein is not intended to be limiting, since the scope of the present invention will be limited only by the appended claims.

Unless defined otherwise, all technical and scientific terms used herein have the same meaning as commonly understood by one of ordinary skill in the art to which this invention belongs. Although any methods and materials similar or equivalent to those described herein may be used in the practice or testing of the present invention, the preferred methods and materials are now described.

In this specification and the appended claims, the singular forms “a”, “an”, and “the” include plural references unless the context clearly dictates otherwise.

In one aspect, the present invention provides a solid porous support suitable for array analysis having first and second surfaces, and comprising channels extending from said first surface to said second surface, characterized in that at least one conductive material is applied to predefined regions on said first surface and/or on said second surface and/or inside the channels contained within said solid porous support.

Solid Porous Support

Within the present specification the terms “pore” and “channel” are used interchangeably and refer to a minute opening that enables matter, in particular solids, liquids or gases, to be absorbed or passed through. Further, in the context of the present invention the term “porous support” denotes a support possessing a plurality of said pores or channels. Particularly, where said pores or channels allow flow-through of matter, the support is likely to be permeable. Accordingly, in one embodiment of the present invention said solid porous support is a flow-through support. The support may be in the form of, for example, sheets, films or membranes. Further, as understood in the present specification, the term “first and second surfaces of a support” signifies the outer top and bottom sides of said support. For a porous support, said first and second surfaces may therefore be physically distinct surfaces interconnected by an intermediate porous material having a plurality of pores or channels, or may be an integral part of the porous material.

Further, in the context of the present invention said pores or channels, especially if said pores or channels allow flow-through of matter, may be discrete, branched or partially branched. For example, a microfabricated nanochannel glass (NCG) material disclosed in EP 0 725 682 B1 comprises regular geometric arrays of parallel discrete pores or channels. Said pores or channels are individually distinct and unconnected in said NCG material. In contrast, as known in the art, partially branched pores or channels are formed by anodization of inorganic membranes. Anodization, i.e. a manufacturing process through which for example a metal oxide membrane is obtained, typically results in so-called nucleation of smaller pores at the bottom side of the membrane. Said smaller pores which extend from the bottom surface provide a branching to each larger pore that extends from the top surface (Rigby et al. 1990; in “Transactions of the Institute of metal Finishing”, vol. 68(3), p. 95-98).

For the purposes of array analysis, the support according to the present invention may be composed of any material which permits immobilization of desired target molecules. In addition, where covalent immobilization of biological molecules is contemplated, the support should be activatable with reactive groups capable of forming a bond, which may be covalent, with the molecule to be immobilized. For the purposes of cell-based assays, the support may be composed of any material which permits culturing of living cells or organisms. For the purposes of spectroscopy assays, the support may be composed of any material that will not interfere with the required optical measurements. For the purposes of assays, in which voltage gradient and/or electric current will be applied to the conductive material(s) deposited on the solid porous support, the support may be preferably composed of a material with low electrical conductivity. For the purposes of cell adherence in array format and cell response upon localized drug treatment, the impendance measured at localized electro surfaces may be used. For the purposes of assays, in which heat will be supplied to or dissipated from the sample by means of the conductive material(s) deposited on the solid porous support, the support may be preferably composed of a material with low thermal conductivity. In case of all applications, the material of the support should not melt or otherwise substantially degrade under the conditions used during functioning.

A number of materials suitable for use in supports according to the present invention have been described in the art. Exemplary supports suitable for use in the present invention comprise materials including acrylic, acrylamide, methylene-bis-acrylamide, dimethylaminopropylmethacrylamide, styrenemethyl methacrylate copolymers, ethylene/acrylic acid, acrylonitrile-butadienestyrene (ABS), ABS/polycarbonate, ABS/polysulfone, ABS/polyvinyl chloride, ethylene propylene, ethylene vinyl acetate (EVA), nitrocellulose, polycarylonitrile (PAN), polyacrylate, polycarbonate, polybutylene terephthalate (PBT), polyethylene terephthalate (PET), polyethylene (including low density, linear low density, high density, cross-linked and ultra-highA molecular weight grades), polypropylene homopolymer, polypropylene copolymers, polystyrene (including general purpose and high impact grades), polytetrafluoroethylene (PTFE), fluorinated ethylene-propylene (FEP), ethylene-tetrafluoroethylene (ETFE), perfluoroalkoxyethylene (PFA), polyvinyl fluoride (PVF), polyvinylidene fluoride (PVDF), polychlorotrifluoroethylene (PCTFE), polyethylene-chlorotrifluoroethylene (ECTFE), polyvinyl alcohol (PVA), silicon styreneacrylonitrile (SAN), styrene maleic anhydride (SMA), and glass. Further exemplary suitable supports comprise mixtures of at least two of the above-mentioned materials.

Other exemplary suitable materials for the manufacture of supports according to the present invention include metal oxides. Metal oxides provide supports having both high channel density and high porosity, which allows for high density arrays. Metal oxides also offer good thermal and chemical resistance. In addition, metal oxide membranes, especially if wet, are transparent for visible light, thus allowing for assays using optical detection techniques. Furthermore, metal oxides supports are relatively cheap and their production does not require any typical microfabrication technology. Exemplary metal oxides suitable for the manufacture of supports according to the present invention comprise, among others, oxides of aluminium, tantalum, titanium, and zirconium, as well as alloys of two or more metal oxides and doped metal oxides and alloys containing metal oxides. Also suitable for the manufacture of supports according to the present invention are mixtures or alloys of two or more metal oxides, metal oxides enriched with “doping” materials, and alloys comprising at least one metal oxide. Accordingly, in one embodiment of the present invention said solid porous support is a metal oxide support.

Particularly suitable metal oxide supports or membranes for use as supports according to the present invention will be anodic oxide films. As known in the art, metallic aluminium may be anodized in an electrolyte to produce an anodic oxide film. In said anodic oxide film a system of larger pores extend from its one face and interconnects with a system of smaller pores extending from the other face. Pore size is determined by the minimum diameter of the smaller pores, while flow rates are largely determined by the length of the smaller pores, which can be made very short. Accordingly, said films or membranes will comprise oriented through-going partially branched channels with well-controlled diameter and useful chemical surface properties. WO 99/02266, which describes the use of Anopore™, is exemplary in this respect, and is specifically incorporated by means of reference in the present invention. Accordingly, in one embodiment of the present invention, said metal oxide is aluminium oxide.

Useful thicknesses of the metal oxide supports or membranes suitable for use as supports according to the present invention may for instance range from 10 μm to 150 μm (including thicknesses of 20, 30, 40, 50, 60, 70, 80, 90, 100, 110, 120, 130 and 140 μm). A particular suitable example of support thickness is 60 μm. A suitable support pore diameter ranges from 150 to 250 nm including 160, 170, 180, 190, 200, 210, 220, 230 and 240 nm. A particular suitable example of pore diameter is 200 nm. These dimensions are not to be construed as limiting the present invention.

Conductive Material

It is an object of the present invention to provide for a solid porous support suitable for array analysis, wherein at least one conductive material is applied to predefined regions of said solid porous support. In the context of the present specification, the term “conductive material” refers to a material that is capable of transmitting electrical current and/or heat and/or acoustic waves (sound). In turn, the term “conductivity” denotes a quantitative measure that describes said capability of a material to transmit electrical current and/or heat and/or sound.

According to one embodiment of the present invention, the conductivity of said at least one conductive material may be higher, equal to or lower than the conductivity of said solid porous support.

In a further embodiment of the present invention, the conductivity of said at least one conductive material may be higher than the conductivity of said solid porous support.

In another embodiment of the present invention, the conductivity of said at least one conductive material refers to its electrical conductivity or thermal conductivity or to a combination of the two. The term “electrical conductivity” refers to the ability of a material to transmit electrical current, while the term “thermal conductivity” refers to the ability of a material to transmit heat.

One useful function of the conductive material(s) applied to the solid porous support may be to form a high-precision grid or mask delineating individual compartments on the surface(s) of the support or within the support. Another useful function of the conductive material(s) applied to the solid porous support is to form a part of an electronic circuit on the surface(s) of and/or within the support.

Said conductive material(s) applied to the support may be in direct or indirect contact with the sample being analyzed on the support. Therefore, depending on the nature of the particular assay, the conductive material(s) may also contribute to the analysis reactions occurring in said sample. For example, the conductive material(s) may be used:
to transfer heat from an external heat source to the sample;
to increase, decrease or maintain at a constant level the temperature of the sample;
especially where such sample comprises living cells or organisms, the temperature of the sample may be maintained at a level optimal to support the growth of said living cells or organisms, or may be increased above or decreased below said optimal level for assays which may require such conditions;
to deliver voltage potential and/or electrical current to the sample, for example to attract or repulse charged molecules within the sample to or from the individual compartments on the surface(s) of or within the support;
to facilitate electrophoresis in the sample;
to facilitate delivery of exogenous nucleic acids, peptides, proteins or other molecules to living cells or organisms by electroporation;
to activate specific properties of living cells or organisms by exposing said cells or organisms to voltage potential and/or electrical current;
to attract charged molecules to specifically to localized voltage-activated areas for localized binding of molecules to produce custom arrays;
to enhance stringency of binding of molecules by voltage-based selection;
to measure electrical, electrochemical and electrochemiluminescence properties of the sample;
to measure impendence at localized electro surfaces for the purposes of cell adherence in array format and cell response upon localized drug treatment;
to transiently or permanently activate or inactivate specific molecules attached to the surface of the conductive material(s) or present close to the surface of the conductive material(s), such as for example proteins, enzymes, or catalysts, by exposing said specific molecules to voltage and/or electrical current;
to comprise specific “detector” molecules linked covalently or non-covalently to the surface of the conductive material(s) that may react with or bind to select components within the sample, wherein such “detector” molecules may comprise for example nucleic acids and synthetic variants thereof such as PNA's or LNA's, proteins, oligopeptides, polypeptides, glycoproteins, proteoglycans, antibodies, receptors, hormones, agonists, antagonists, lipids, glycolipids, carbohydrates, drugs, enzyme co-factors, small molecules, or any combination thereof;
to detect, for example electrochemically, binding of a given component or molecule comprised in the sample to said “detector” molecule(s);
to enable measuring the spectral properties of select molecules comprised in the sample for example by surface-enhanced Raman spectroscopy.

Most metals in their metallic state display excellent electrical and thermal conductivity. Moreover, many metals can be applied on solid supports using methods known in the field of microelectronics that result in high precision of deposition. In accordance, in one embodiment of the present invention, said at least one conductive material applied to the solid porous support may be chosen from the group comprising a metal in its metallic form, a combination of at least two metals in their metallic form, or an alloy of at least two metals in their metallic form.

Carbon and most metals may be used as conductive material(s) in the context of the present invention, provided metals in their metallic form are sufficiently stable under the conditions used during functioning of the support. In a further embodiment of the present invention, said metal is chosen from the group comprising aluminium, beryllium, chromium, cobalt, copper, gold, iron, lead, manganese, mercury, nickel, molybdenum, niobium, palladium, platinum, rhodium, silver, tellurium, tin, titanium, tungsten, zinc, zirconium, and yttrium. In one suitable example, the metal useful as a conductive material in the present invention is chosen from aluminium, gold, iron, lead, platinum, palladium, and copper.

While metal(s) may be especially useful as conductive material(s) to be applied on solid porous supports according to the present invention, non-metallic conductive materials may also be applied on said supports in the present invention. For example, certain organic polymers show good electrical conductivity. Thus, it is known in the art that organic polymers with a conjugated system of π-electrons can conduct electric current after “doping” with appropriate doping agents that facilitate the electrical conductivity of said organic polymers. Such organic polymers may comprise for example polyacetylene, polyaniline or polyaniline-based polymers, including leuco-emeraldine-base (LEB), emeraldine-base (EB), and pernigraniline-base (PNB) forms of polyaniline, polypyrrole and polypyrrole-based polymers, polythiophene and polythiophene-based polymers, polyethyleneoxide and polyethyleneoxide-based polymers, poly(para-phenylene) and poly(para-phenylene)-based polymers, and poly(p-phenylenevinylene) and poly(p-phenylenevinylene)-based polymers, or a mixture or a co-polymer thereof. Suitable doping agents may for example comprise lithium, sodium, potassium, calcium, salts or derivatives of ammonium, salts of boron or compounds comprising boron such as BF₆, iodine, bromine, chlorine, compounds comprising phosphor such as PF₆, salts of arsenic or compounds comprising arsenic such as AsF₆.

Another group of conductive materials that may be applied to porous supports in the present invention are semiconductors. Suitable semiconductors for use as conductive material(s) on the porous support may comprise any of the semiconductors commonly used in other devices, such as electronic and optical-electronic devices, comprising intrinsic and extrinsic (both n-type and p-type) semiconductors, such as by way of example and not limitation silicone-based semiconductors, InP, GaAs, or InGaAsP, or combinations thereof.

Another group of conductive materials that may be applied to porous supports comprises for example carbon, carbon black or graphite.

It is an object of the present invention to provide for a solid porous support suitable for array analysis, wherein at least one conductive material is applied to predefined regions of said solid porous support. In the context of the present invention, said predefined regions and the resulting patterns and geometries of the applied conductive material(s) may vary between different embodiments.

Accordingly, in one embodiment of the present invention, said conductive material partially covers the first surface and/or the second surface of the solid porous support.

In a particularly useful embodiment of the present invention, said conductive material forms a grid or mask that covers selected regions of the first surface and/or of the second surface of the solid porous support. Such grid or mask will delineate on the first surface and/or on the second surface of the solid porous support distinct regions not containing any deposited conductive material(s), separated from each other by a network of horizontal and vertical lines formed by said conductive material(s). Said regions will be available for array analysis. Depending on the application requirements, said lines will be uniformly or non-uniformly spaced. A useful line width in the present invention ranges between 200 nm and 1 cm, including the outer limits; another useful line width ranges between 1 μm and 50 μm, including the outer limits. Depending on the application a particular useful line width may range between 5 μm and 20 μm, including the outer limits.

Where said grid comes in direct or indirect contact with the sample, the conductive qualities of the material(s) forming the grid may be utilized in one or more of the ways described above to manipulate the conditions of the analysis being performed in said regions.

In another embodiment of the present invention, said at least one conductive material may form a part of an electronic circuit deployed on the first surface and/or on the second surface of the solid porous support. Said electronic circuit may be in a direct or indirect contact with a sample and may be used for example:
to deliver voltage potential and/or electrical current to the sample, for example to attract or repulse charged molecules within the sample to or from the individual compartments on the surface(s) of and/or within the support;
to facilitate electrophoresis in the sample;
to facilitate delivery of exogenous nucleic acids, peptides, proteins or other molecules to living cells or organisms by electroporation;
to activate specific properties of living cells or organisms by exposing said cells or organisms to voltage potential and/or electrical current;
to attract charged molecules to specifically to localized voltage-activated areas for localized binding of molecules to produce custom arrays;
to enhance stringency of binding of molecules by voltage-based selection;
to measure electrical, electrochemical and electrochemiluminiscence properties of the sample;
to measure impendance at localized electro surfaces for the purposes of cell adherence in array format and cell response upon localized drug treatment;
to transiently or permanently activate or inactivate specific molecules attached to the surface of the conductive material(s) or present close to the surface of the conductive material(s), such as for example proteins, enzymes, or catalysts by exposing said specific molecules to voltage and/or electrical current;

In another embodiment of the present invention, at least one conductive material is deposited on said first and second surfaces, and said at least one conductive material differs between said first surface and said second surface of said solid porous support. Where said conductive materials deposited on the opposite surfaces of the support may be in contact with an electrolyte solution located within the channels of the support, electrochemical reactions occurring on said conductive materials may create a battery cell.

In another embodiment of the present invention, said at least one conductive material forms one or more distinct regions on the first surface and/or the second surface of the solid porous support, separated from each other by regions not containing any deposited conductive material(s), which may for example be used to allow for localized uptake or exchange of compounds and reagents.

In another embodiment of the present invention, said conductive material(s) will be allowed to enter at predefined regions the channels contained within the solid porous support. Said conductive material may fill said channels only partially, adjacent to the first surface and/or to the second surface of said solid porous support. Depending on the application requirements, the height or thickness of such partial filling may correspond to 1 to 99% of the height or thickness of the support. The support height may range from 10 to 150 μm. A more useful support height or support thickness ranges between 20 and 100 μm. An even more useful support height or support thickness ranges between 30 and 80 μm. An even more useful support height or support thickness ranges between 40 and 70 μm. A particular suitable support thickness within the present invention is 60 μm.

Alternatively, in another embodiment of the present invention, said conductive material(s) will at predefined regions completely fill the channels of said solid porous support. In doing so, said conductive material(s) may create a three-dimensional grid or mask through the solid porous support. Such grid or mask would delineate within the support distinct compartments, in which the channels would not contain any deposited conductive material(s), separated from each other by a network of horizontal and vertical three-dimensional lines formed by said conductive material(s) through the entire height or thickness of the support. Said compartments would be available for array analysis. Depending on the application requirements, said lines would be uniformly or non-uniformly spaced. A useful line width in the present invention ranges between 200 nm and 1 cm, including the outer limits; another useful line width ranges between 1 μm and 50 μm, including the outer limits. Depending on the application a particular useful line width may range between 5 μm and 20 μm, including the outer limits.

Where said grid comes in direct or indirect contact with the sample, the conductive qualities of the material(s) forming the grid may be utilized in one or more of the ways described above to manipulate the conditions of the analysis being performed in said compartments.

In yet another embodiment of the present invention, said at least one conductive material will at predefined regions form a layer covering solely the walls of the channels contained within the solid porous support. Depending on the nature of the particular assay, specific properties of said layer may contribute to the process of analysis. Examples may comprise:
conducting heat from an external heat source to the sample present within the channels;
dissipating the heat generated in the sample as a result of the analysis process;
increasing, decreasing or maintaining at a constant level the temperature of the sample;
delivering voltage potential and/or electrical current to the sample, for example to attract or repulse charged molecules within the sample to or from the individual reaction compartments on the surfaces of and/or within the support;
facilitating electrophoresis in the sample;
facilitating delivery of exogenous nucleic acids, peptides, proteins or other molecules to living cells or organisms by electroporation;
activating specific properties of living cells or organisms by exposing said cells or organisms to voltage potential and/or electrical current;
attracting charged molecules to specifically to localized voltage-activated areas for localized binding of molecules to produce custom arrays;
enhancing stringency of binding of molecules by voltage-based selection;
measuring electrical, electrochemical and electrochemiluminescence properties of the sample;
measuring impendence at localized electro surfaces for the purposes of cell adherence in array format and cell response upon localized drug treatment;
transiently or permanently activating or inactivate specific molecules attached to the surface of the conductive material(s) or present close to the surface of the conductive material(s), such as for example proteins, enzymes, or catalysts by exposing said specific molecules to voltage and/or electrical current;
comprising specific “detector” molecules linked covalently or non-covalently to the surface of the conductive material(s) that may react with or bind to select components within the sample, wherein such “detector” molecules may comprise for example nucleic acids and synthetic variants thereof such as PNA's or LNA's, proteins, oligopeptides, polypeptides, glycoproteins, proteoglycans, antibodies, receptors, hormones, agonists, antagonists, lipids, glycolipids, carbohydrates, drugs, enzyme co-factors, small molecules, or any combination thereof;
detecting, for example electrochemically, binding of a given substance comprised in the sample to said “detector” molecule(s);
enabling measuring the spectral properties of select molecules comprised in the sample for example by surface-enhanced Raman spectroscopy.

It will be appreciated that a porous support may also comprise a combination of the preceding embodiments, wherein at least one conductive material will at predefined regions completely fill the channels of said solid porous support, while the same or another conductive material(s) will at other predefined regions form a layer covering solely the walls of the channels contained within the solid porous support. This combination may for example create a three-dimensional grid or mask through the solid porous support that would delineate within the support distinct compartments, in which the non-blocked channels would contain deposited conductive material(s) solely on their walls.

In one embodiment the present invention further anticipates that at least one conductive material may be deposited in a predefined pattern on the first surface and/or on the second surface of said solid porous support, and the same or another conductive material(s) may also enter the channels within the support at identical or different predefined regions. It will be appreciated that within this embodiment, the conductive material(s) deposited on the first surface of the support may or may not be the same as the conductive material(s) deposited on the second surface, and that the conductive material(s) that enter the channels of the support may or may not be the same as the conductive material(s) deposited on one of the surfaces. Also, different conductive material(s) may enter the channels of the support at different predefined regions of the support and different conductive material(s) may be deposited at different predefined regions of the first and/or second surfaces of the support.

In another embodiment of the present invention, said at least one conductive material is deposited in one or more layers. It will be appreciated that when more than one layer of conductive material(s) is applied to the porous support, the different layers may be composed of the same conductive material(s), or alternatively, may comprise different conductive materials. The different layers may be applied to identical regions of the support, or to partially overlapping regions of the support, or to different regions of the support. The different layers may have either identical or similar or different thicknesses. The layers together may form a three-dimensional pattern on the porous support. One or more outer layer may serve to protect one or more layer deposited below, i.e. closer to the support, from physical or chemical damage.

It is a further object of the present invention to provide a method for the manufacture of the solid porous support according to the present invention, wherein said at least one conductive material is applied to said solid porous support by a step chosen from the group comprising sputtering, physical vapor deposition, thermal spraying, electroplating, precipitation from solution, physical contact or heating, direct inkjet printing, and self-assembly of particles. The above methods are well-known in microelectronics for use in depositing metals or semiconductors on resins. For example in sputtering, metal vapor is formed by bombarding metals with ionized inert gas, such as for example argon, and said metal vapor is subsequently deposited on the cooler surface of the support. Physical vapor deposition comprises the steps of first vaporizing a metal or semiconductor using heat or a beam of electron particles and subsequently depositing the vapors on the cooler surface of the support. In thermal spraying, metals are melted and atomized by compressed air and the atomized metal is propelled by the compressed air to the target support. In electroplating a metal is deposited onto an object by applying a negative charge to said object and immersing said object into a salt of said metal; the dissolved cations of said metal are reduced on the surface of said object to a metallic form of the metal. In precipitation from solution, metal ions are electrochemically reduced to their metallic form on a surface of the support or on another surface provided on the support . Alternatively, polymer molecules may precipitate out from a polymer solution. In deposition by physical contact or pressure a thin sheet of metal may be applied directly to a surface of support by pressure or heat. Direct inkjet printing comprises direct printing of liquid containing metallic nanoparticles. After evaporation of the liquid the metallic nano-particles come to close contact and conduct. Alternatively, a polymer solution can also be deposited by direct inkjet printing, followed by solidification of the polymer. In self-assembly, large clusters of molecules precipitate from the solution. It should be understood that other methods used in the art for deposition of metals, mixtures of metals or alloys of metals, semiconductors, and organic polymers, which were not explicitly mentioned above, are also suitable for deposition of metals on porous support in the context of the present invention. Moreover, improvements and alterations to said methods will also find application in the context of the present invention.

Molecular Analysis

With microarray analysis as the one of the preferred intended uses of the masked supports according to the present invention, the provision of biological molecules within the unmasked porous structure of the support is contemplated within the present invention. Said biological molecules may also be linked to, adsorbed to, or provided on the conductive material(s) deposited at predefined regions of one or both surfaces of the porous support or within the channels of the support in some embodiments of the present invention. As such, the present invention also provides for masked solid porous supports comprising within the unmasked channels or within channels comprising a layer of conductive material(s) biomolecules. Said biomolecules may represent a library of compounds useful in e.g. drug screening practices. Said compound(s) may be present in dried or other concentrated state after applying e.g. slow evaporation, vacuum drying, freeze drying methods or by e.g. by blowing air or an inert gas such as e.g. helium above and below the porous support. Said compound(s) may be present in the form of e.g. lyophilised compounds or, fixed to the surface or, alternatively, they may be present in solution—these forms of compound occurrences are well known in the art.

General suitable classes of compounds for use in the masked solid supports according to the present invention are well known in the art and include, by way of example and not limitation, natural compounds derived e.g. from plants with defined therapeutic applications, chemically synthesized compounds, compounds derived from combinatorial chemistry, peptide-based compounds, peptide derivatives and the like.

Biologically active libraries may include proteolytic enzymes such as for example serine proteases like trypsin, non-proteolitic enzymes including inducer molecules, chaperone proteins, antibodies and antibody fragments, agonists, antagonists, inhibitors, G-coupled protein receptors (GPCRs), non-GPCRs, and cytotoxic and anti-infective agents. Examples of libraries without disclosed biologically activity may include scaffold derivatizations, acyclic synthesis, monocyclic synthesis, bicyclic and spirocyclic synthesis, and poly and macrocyclic synthesis, or compounds which interact with any of the above-mentioned molecules. All these libraries are well known in the art. In particular, inducer molecules, chaperone proteins, hormones, oligopeptides, nucleic acids and synthetic variants thereof such as PNA's or LNA's, agonists, antagonists, inhibitors of cellular functions, enhancers of cellular functions, transcription factors, growth factors, differentiation-inducing agents, secondary metabolites, toxins, glycolipids, carbohydrates, antibiotics, mutagens, drugs, RNAi, DNA or RNA vectors, plasmids, and any combination thereof are suitable compounds for use within the present invention.

Compounds obtained through combinatorial and so-called fast synthesis may be equally suitable. For applications wherein a high-complexity analysis is required, the use of external devices is also contemplated within the present invention. In this context; the use of a so-called supply chamber is contemplated by the present invention. European application No. 03447276.1 related to such supply chambers is hereby incorporated by reference.

A supply chamber allows the delivery of reactants or biomolecules or compounds to the solid support which otherwise may suffer impracticalities; e.g. which may clog the capillaries of e.g. a spotting device, or needles or tips of a liquid handling device. A supply chamber as such gives access of its content to at least one array within an array of arrays to which it is attached by either physical attachment or by mechanical attachment or merely by being in liquid contact with the array. A supply chamber may also facilitate electronic connection of the circuit of the conductive material on the porous substrate.

Said physical and/or liquid contact may be reversible and allow subsequent supply chambers with diverse contents to be combined with a same solid porous support. A removable supply chamber offers the advantage and flexibility of transferring compounds to the solid support and immediate interruption of said supply by removal of the chamber.

Compounds may be stored in the supply chamber after a drying treatment, after which they can be dissolved again, later on when an assay needs to be performed. Upon compound dissolution; e.g. when in contact with an appropriate liquid or buffer, the compounds diffuse from the supply chamber into and through the pores of the porous solid support.

General Applications

The solid porous support according to the present invention is useful in a number of applications.

In one embodiment, the present invention provides for the use of a solid support as described herein for microarray analysis.

In another embodiment, the present invention provides for the use of a solid support as described herein for cell-based assays.

In a further embodiment, the present invention provides for the use of a solid support as described herein for drug-screening assays.

In a yet another embodiment, the present invention provides for the use of a solid support as described herein for chemical reaction assays.

In a further embodiment, the present invention provides for the use of a solid support as described herein for electrochemical detection assays.

In yet a further embodiment, the present invention provides for the use of a solid support as described herein for electrophoresis.

In a further embodiment, the present invention provides for the use of a solid support as described herein for spectroscopy assays.

It is a further object of the present invention to provide a device that comprises the solid porous support as provided by the present invention.

It is a further object of the present invention to provide a device comprising a solid porous support as defined above for use in cell adhesion based impendence measurements.

It is a further object of the present invention to provide a device comprising a solid porous support as defined above for use in cell electroporation.

The following figures and examples serve to illustrate the present invention but are in no way construed to limit the present invention.

### SHORT DESCRIPTION OF THE FIGURES

FIG. 1 illustrates a solid porous support sputtered with gold;

FIG. 1a shows a solid porous support sputtered with gold through a masking process; and

FIG. 1b shows a light transmission image on microscope BX41 4× objective of gold a solid porous support sputtered with gold, the black color corresponds to the gold masked substrate.

FIG. 2 illustrates a gold sputtered solid porous support in a cell-based assay. s, substrate; m, gold particles; b, bacterial growth; g; increased bacterial growth. The arrow represents 2.5 mm.

FIG. 2a shows a light transmission based image of gold sputtered on a solid porous substrate through masking process; and

FIG. 2b shows a light transmission image of normal bacterial growth on a solid porous support (“living chip”) showing localized MRSA cultured growth.

### EXAMPLE

### Sputtering of Gold Particles on a Solid Porous Support

The present invention provides electronic addressing for customized array generation, improved binding stringency by active attraction and repulsion and other advantages such as electrophoresis, electroporation and growth based cell arrays. Metal particles can be delivered on a non-conductive porous support through sputtering (including deposition guided by a photolithographic mask), electroplating, precipitation and self-assembling particles, while maintaining the basic properties of the porous membrane. The metal particles can either partly of fully penetrate the porous support depending on the application.

The solid porous supports were prepared by thermal evaporation of gold according to methods described in the literature The process was performed in two subsequent steps, in which the relative orientation of the mask was changed by 90 degrees (Inukai et al, Jpn. J. Appl. Phys. 1991, 30, 3496-3502).

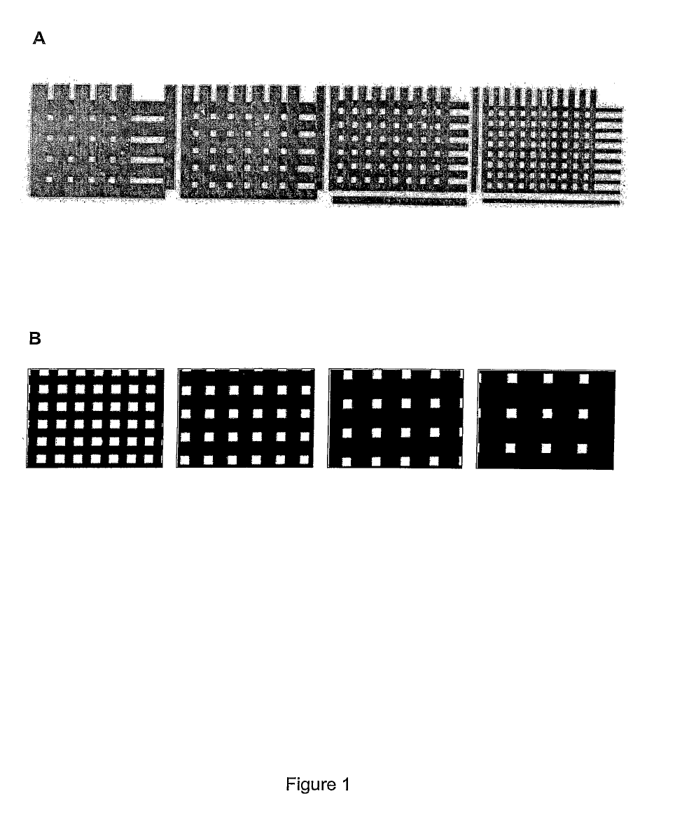

In FIG. 1, two images are shown of gold sputtered masked flow-through array substrate (Anopore™) at various mesh sizes and various thicknesses in the pm scale. It further shows that the porous support is almost completely transparent which can be used in imaging techniques.

### The Functionality of the Solid Porous Support is Maintained After Gold Deposition

The functionality of a gold sputtered solid porous support (Anopore™) which was prepared as described above was tested in a so-called “living chip” application. In this case bacteria or other cells are plated on top of the flow-through membrane. Nutrients, required for the growth of the cells were supplied to the cells by plating the flow-through membrane on top of a blood agar nutrient plate.

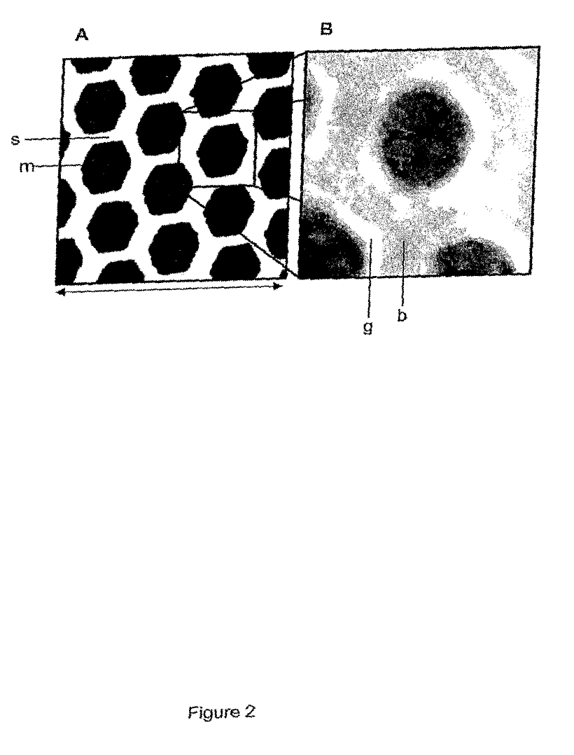

FIG. 2 shows growing bacteria, Staphylococcus aureus, after 24-hours growth next to gold patches contained on the solid porous support, which is visualized by transmission light microscopy. The bacterial growth confirms that the functionality of the solid support is maintained after gold deposition.

The integration of microelectronics with cell biology and molecular biology based micro assays allows both electronic readout of cell properties and biochemical assays as well ability to detect cell-markers using reporter probes operating in the transmission and fluorescent space or perform label-free detection on the basis of impedance changes.

1-30. (canceled)

31. A solid porous support suitable for array analysis having a first and a second surface, and comprising channels extending from said first surface to said second surface, characterised in that at least one conductive material is applied to predefined regions on said porous support to create a three-dimensional grid or mask through the porous support to delineate compartments for exposure to samples or reactants.

32. The solid porous support according to claim 31, wherein the conductivity of said at least one conductive material is higher, equal to or lower than the conductivity of said solid porous support.

33. The solid porous support according to claim 31, wherein the conductivity of said at least one conductive material is higher than the conductivity of said solid porous support.

34. The solid porous support according to claim 32, wherein the conductivity is chosen from a group comprising electrical conductivity, thermal conductivity, or a combination thereof.

35. The solid porous support according to claim 31, wherein said at least one conductive material is chosen from the group comprising carbon, a metal in its metallic form, a combination of at least two metals in their metallic form, or an alloy of at least two metals in their metallic form.

36. The solid porous support according to claim 35, wherein said metal is chosen from the group comprising aluminium, beryllium, chromium, cobalt, copper, gold, iron, lead, manganese, mercury, nickel, molybdenum, niobium, palladium, platinum, rhodium, silver, tellurium, tin, titanium, tungsten, zinc, zirconium, and yttrium.

37. The solid porous support according to claim 31, wherein said at least one conductive material is deposited in one or more layers.

38. The solid porous support according to claim 31, wherein said at least one conductive material partially covers said first surface and/or said second surface of said solid porous support.

39. The solid porous support according to claim 38, wherein said at least one conductive material forms a part of an electronic circuit deployed on said first surface and/or on said second surface of the solid porous support.

40. The solid porous support according to claim 38, wherein said at least one conductive material forms a grid or a mask covering selected regions of said first surface and/or said second surface of said solid porous support.

41. The solid porous support according to claim 38, wherein said at least one conductive material forms one or more distinct regions on said first surface and/or on said second surface of said solid porous support, separated from each other by regions not containing any deposited conductive material(s).

42. The solid porous support according to claim 31, wherein said at least one conductive material is deposited on said first and second surfaces, and wherein said at least one conductive material differs between said first surface and said second surface of said solid porous support.

43. The solid porous support according to claim 31, wherein said at least one conductive material at predefined regions enters said channels contained within said solid porous support.

44. The solid porous support according to claim 43, wherein said at least one conductive material at predefined regions completely fills said channels contained within said solid porous support.

45. The solid porous support according to claim 43, wherein said at least one conductive material at predefined regions forms a layer covering solely the walls of said channels contained within said solid porous support.

46. The solid porous support according to claim 31, wherein said at least one conductive material is deposited in a predefined pattern on said first surface and/or on said second surface of said solid porous support, and wherein said at least one conductive material also at predefined regions enters said channels contained within said solid porous support.

47. The solid porous support according to claim 31, wherein said solid porous support is a flow-through support.

48. The solid porous support according to claim 31, wherein said solid porous support is a metal oxide support.

49. The solid porous support according to claim 48, wherein said metal oxide is aluminium oxide.

50. A method for the manufacture of the solid porous support according to any of the preceding claims, wherein said at least one conductive material is applied to said solid porous support by a step chosen from the group comprising sputtering, physical vapor deposition, thermal spraying, electroplating, precipitation from solution, physical contact or heating, direct inkjet printing, and self-assembly of particles.

51. A device comprising solid porous support according to claim 31.

52. A device comprising solid porous support according to claim 31 for use in cell adhesion based impendence measurements.

53. A device comprising solid porous support according to claim 31 for use in cell electroporation.
